(19) United States
(12) Patent Application Publication
(10) Pub. No.: US 2025/0300069 A1
(43) Pub. Date: Sep. 25, 2025

(54) SEMICONDUCTOR DEVICE CONTAINING SELF-ALIGNED VIA STRUCTURES AND ETCH-STOP DIELECTRIC LAYER AND METHODS FOR FORMING THE SAME

(71) Applicant: SANDISK TECHNOLOGIES LLC, ADDISON, TX (US)

(72) Inventors: Yoshifumi OYA, Yokkaichi (JP); Masaki ADACHI, Yokkaichi (JP); Yasuo KASAGI, Yokkaichi (JP)

(21) Appl. No.: 18/615,626

(22) Filed: Mar. 25, 2024

(51) Int. Cl. H01L 23/522; H01L 21/768; H01L 23/528; H01L 23/532

(52) U.S. Cl. CPC H01L 23/5226; H01L 21/76804; H01L 21/76819; H01L 21/76829; H01L 21/76883; H01L 23/5283; H01L 23/5329

(57) ABSTRACT

A device includes a first interconnect-level dielectric layer embedding a first conductive interconnect structure that includes a first conductive line portion, a first etch-stop dielectric layer including a first line-shaped opening therein, a first complementary dielectric fill material portion filling the first line-shaped opening and having a pair of bottom edges that coincide with a pair of edges of a top surface of the first conductive line portion, and a second interconnect-level dielectric layer overlying the first etch-stop dielectric layer and embedding a second conductive interconnect structure that includes a conductive via portion that vertically extends through a lower portion of the second interconnect-level dielectric layer and through the first complementary dielectric fill material portion, and has a first bottom surface segment that contacts the first conductive line portion.

### FIELD

The present disclosure relates generally to the field of semiconductor devices, and particularly to a semiconductor device containing self-aligned via structures employing a single etch-stop dielectric layer and methods for forming the same.

### BACKGROUND

Scaling of conductive interconnect structures to smaller dimension in semiconductor device manufacturing increases various issues related to open circuits for conductive interconnect structures to be electrically connected, and electrical short circuits for conductive interconnect structures to be electrically isolated.

### SUMMARY

According to an aspect of the present disclosure, a device comprises: a first interconnect-level dielectric layer embedding a first conductive interconnect structure that comprises a first conductive line portion; a first etch-stop dielectric layer comprising a first etch-stop dielectric material and including a first line-shaped opening therein; a first complementary dielectric fill material portion filling the first line-shaped opening and having a pair of bottom edges that coincide with a pair of edges of a top surface of the first conductive line portion; and a second interconnect-level dielectric layer overlying the first etch-stop dielectric layer and the first complementary dielectric fill material portion and embedding a second conductive interconnect structure that comprises a conductive via portion that vertically extends through a lower portion of the second interconnect-level dielectric layer and through the first complementary dielectric fill material portion, and has a first bottom surface segment that contacts the first conductive line portion.

According to another aspect of the present disclosure, a method of forming a device comprises: forming a first interconnect-level dielectric layer; forming a first etch-stop dielectric layer comprising a first etch-stop dielectric material and including a first line-shaped opening therein over the first interconnect-level dielectric layer; forming a first line cavity in an upper portion of the first interconnect-level dielectric layer by transferring a pattern of the first line-shaped opening into an upper portion of the first interconnect-level dielectric layer; forming a first conductive interconnect structure that comprises a first conductive line portion in the first interconnect-level dielectric layer, wherein the first conductive line portion is formed within a volume of the first line cavity and has a top surface located below a horizontal plane including a top surface of the first etch-stop dielectric layer; forming a first complementary dielectric fill material portion over the first conductive interconnect structure within the first line-shaped opening, wherein a top surface of the first complementary dielectric fill material portion is formed within the horizontal plane including a top surface of the first etch-stop dielectric layer; forming a second interconnect-level dielectric layer over the first etch-stop dielectric layer and the first complementary dielectric fill material portion; and forming a second conductive interconnect structure in the second interconnect-level dielectric layer, wherein the second conductive interconnect structure comprises a conductive via portion that vertically extends through a lower portion of the second interconnect-level dielectric layer and through the first complementary dielectric fill material portion, and has a first bottom surface segment that contacts the first conductive line portion.

### BRIEF DESCRIPTION OF THE DRAWINGS

FIG. 1 is a schematic vertical cross-sectional view of an exemplary structure after formation of semiconductor devices and a contact-level dielectric material layer embedding contact-level conductive interconnect structures according to an embodiment of the present disclosure.

FIG. 2 is a schematic vertical cross-sectional view of the exemplary structure after formation of a first interconnect-level dielectric layer and a first etch-stop dielectric layer according to an embodiment of the present disclosure.

FIG. 3 is a schematic vertical cross-sectional view of the exemplary structure after formation of first line cavities in an upper portion of the first interconnect-level dielectric layer according to an embodiment of the present disclosure.

FIG. 4 is a schematic vertical cross-sectional view of the exemplary structure after formation of first via cavities according to an embodiment of the present disclosure.

FIG. 5 is a schematic vertical cross-sectional view of the exemplary structure after formation of first conductive interconnect structures according to an embodiment of the present disclosure.

FIG. 6 is a schematic vertical cross-sectional view of the exemplary structure after vertically recessing the first conductive interconnect structures according to an embodiment of the present disclosure.

FIG. 7 is a schematic vertical cross-sectional view of the exemplary structure after formation of first complementary dielectric fill material portions according to an embodiment of the present disclosure.

FIG. 8 is a schematic vertical cross-sectional view of the exemplary structure after formation of a second interconnect-level dielectric layer and a second etch-stop dielectric layer according to an embodiment of the present disclosure.

FIG. 9 is a schematic vertical cross-sectional view of the exemplary structure after formation of second line cavities in an upper portion of the second interconnect-level dielectric layer according to an embodiment of the present disclosure.

FIG. 10 is a schematic vertical cross-sectional view of the exemplary structure after formation of second via cavities according to an embodiment of the present disclosure.

FIG. 11 is a schematic vertical cross-sectional view of the exemplary structure after formation of second conductive interconnect structures according to an embodiment of the present disclosure.

FIG. 12 is a schematic vertical cross-sectional view of the exemplary structure after vertically recessing the second conductive interconnect structures according to an embodiment of the present disclosure.

FIG. 13 is a schematic vertical cross-sectional view of the exemplary structure after formation of second complementary dielectric fill material portions according to an embodiment of the present disclosure.

FIG. 14 is a schematic vertical cross-sectional view of a first alternative configuration of the exemplary structure according to an embodiment of the present disclosure.

FIG. 15 is a schematic vertical cross-sectional view of a second alternative configuration of the exemplary structure according to an embodiment of the present disclosure.

FIG. 16 is a schematic vertical cross-sectional view of a third alternative configuration of the exemplary structure according to an embodiment of the present disclosure.

### DETAILED DESCRIPTION

The present inventors realized that reducing a pitch of interconnect structures may result in time-dependent dielectric breakdown (TDDB) reliability issues, in which leakage current between neighboring conductive interconnect structures increases over time during device operation. Conductive interconnect structures formed by traditional dual damascene processes at small pitches are prone to device reliability issues associated with overlay misalignment. The misalignment degrades the breakdown voltage of the semiconductor devices. As discussed above, the embodiments of the present disclosure are directed to self-aligned via structures employing a etch-stop dielectric layer and methods for forming the same, the various aspects of which are described below. The embodiment via structures reduce TDDB reliability issues and overlay misalignment, while permitting a reduced pitch of the interconnect structures.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1×10⁻⁵ S/m to 1×10⁵ S/m. As used herein, a “semiconductor material” refers to a material having electrical conductivity in the range from 1×10⁻⁵ S/m to 1 S/m in the absence of electrical dopants therein, and is capable of producing a doped material having electrical conductivity in a range from 1 S/m to 1×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1×10⁵ S/m. As used herein, an “insulator material” or a “dielectric material” refers to a material having electrical conductivity less than 1×10⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1×10⁻⁵ S/m to 1×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “electrically conductive material” refers to a conductive material including at least one electrically conductive element therein. All measurements for electrical conductivities are made at the standard condition.

Dual damascene processes have been extensively employed to form integrated line-and-via structures and conductive interconnect structures embedded within interconnect-level dielectric layers. Since a dual damascene process employs two lithographic exposure steps for the purpose of forming line patterns and via patterns, the dual damascene process may introduce overlay misalignment between the line patterns and the via patterns. This overlay misalignment may induce deleterious effects such as the time-dependent dielectric breakdown (TDDB) due to increased electric field strengths at the misaligned interfaces, leading to a higher probability of dielectric failure. Further, misalignment between conductive interconnect structures formed at different interconnect levels introduce additional variability in the reliability of the conductive interconnect structures.

Embodiments of the present disclosure provide methods for forming self-aligned contacts between conductive interconnect structures formed in different levels, and particularly for integrated line-and-via structures that are formed in different levels. An etch-stop dielectric layer can be employed to mitigate the adverse effects of overlay misalignment in order to reduce electrical short circuits and to suppress TDDB. The etch-stop dielectric layer is formed over a first interconnect-level dielectric layer. A first photoresist layer is applied over the etch-stop dielectric layer, and is lithographically patterned to provide a line pattern therein. Line-shaped openings are patterned in the etch-stop dielectric layer by transferring the line pattern in the first photoresist layer through the etch-stop dielectric layer, and the pattern of the line-shaped openings is subsequently transferred into an upper portion of the first interconnect-level dielectric layer to form first line cavities. A second photoresist layer having a via pattern is formed over the etch-stop dielectric layer, and the via cavities are formed underneath the line cavities entirely within the areas of the line cavities. First conductive interconnect structures are formed in first integrated line-and-via cavities which include the volumes of the line cavities and the volumes of the via cavities. Top surfaces of the first conductive interconnect structures are vertically recessed, and volumes of the opening overlying the first conductive interconnect structures are filled with first complementary dielectric fill material portions. A second interconnect-level dielectric layer is formed over the etch-stop dielectric layer. Second via cavities, which may be second integrated line-and-via cavities, may be formed through the second interconnect-level dielectric layer and the first complementary dielectric fill material portions selective to the etch-stop dielectric layer. Thus, physically exposed surface segments of the first conductive interconnect structures underneath the second via cavities can be self-aligned to the pattern of the openings in the etch-stop dielectric layer. Second conductive interconnect structures including conductive via portions are formed in the second via cavities. The second conductive interconnect structures can be self-aligned to the pattern of the openings in the etch-stop dielectric layer, and TDDB related issues can be reduced. Details of embodiments of the present disclosure are described below with reference to accompanying drawings.

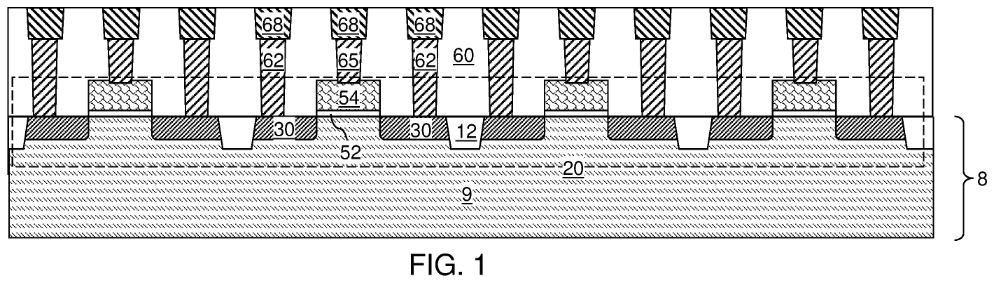

Referring to FIG. 1, an exemplary structure according to an embodiment of the present disclosure is illustrated. The exemplary structure includes a semiconductor substrate 8 including a semiconductor material layer 9. The semiconductor substrate 8 may consist of a semiconductor material, or may be a composite substrate including the semiconductor material layer 9 at the top portion thereof and further including an additional material layer underneath. The semiconductor material layer 9 may comprise any semiconductor material known in the art, such as, but not limited to, an elemental semiconductor material (such as silicon) or a compound semiconductor material. The semiconductor material layer 9 may be single crystalline, polycrystalline, or amorphous. For example, the semiconductor substrate 8 may comprise a single crystal silicon wafer, and the semiconductor material layer 9 may comprise a doped well in the silicon wafer or an epitaxial silicon layer on a top surface of the silicon wafer. Alternatively, the substrate 8 may comprise a silicon on insulator (SOI) substrate, and the semiconductor material layer 9 may comprise a silicon device layer located over an insulating layer. Semiconductor devices 20 can be formed in and/or on the semiconductor material layer 9. Generally, the semiconductor devices 20 may be formed on a top surface of the semiconductor substrate 8. In the illustrated example, the semiconductor devices 20 may comprise field effect transistors including source/drain regions 30, gate dielectrics 52, and the gate electrodes 54. Shallow trench isolation structures 12 may be formed in an upper portion of the semiconductor material layer 9 to provide electrical isolation between neighboring pairs of semiconductor devices 20. Additional semiconductor devices and/or alternative solid state devices (e.g., diodes, capacitors, resistors, etc.) may be formed on the top surface of the semiconductor substrate 8.

Suitable electrodes and interconnects may be provided over the semiconductor devices 20. For example, a contact-level dielectric layer 60 can be formed over the semiconductor devices 20, and a contact-level conductive interconnect structures (62, 65, 68) may be formed in the contact-level dielectric layer 60. For example, the contact-level conductive interconnect structures (62, 65, 68) may comprise source/drain contact via structures (i.e., source and drain electrodes) 62, gate contact via structures 65, and contact-level conductive lines 68.

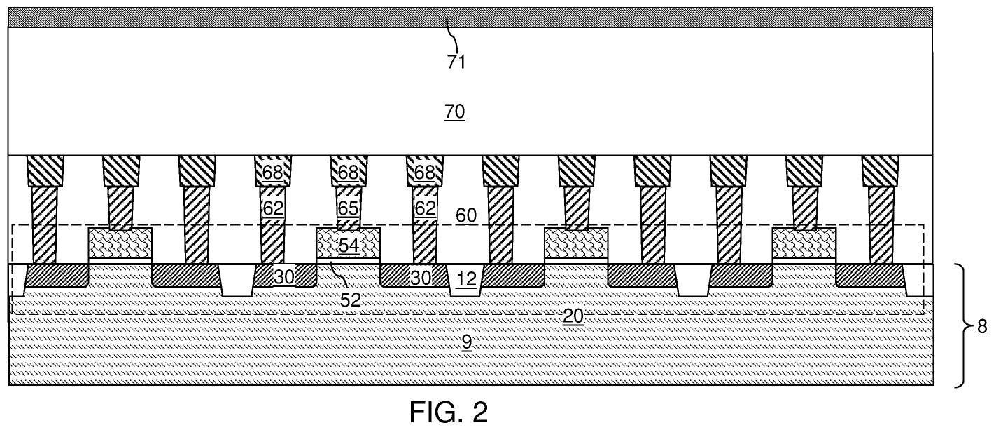

Referring to FIG. 2, a first interconnect-level dielectric layer 70 and a first etch-stop dielectric layer 71 can be formed over the contact-level dielectric layer 60. The first interconnect-level dielectric layer 70 may be formed directly on the contact-level dielectric layer 60 as illustrated in FIG. 2. Alternatively, at least one intervening interconnect-level dielectric layer (not illustrated) embedding intervening conductive interconnect structures (not illustrated) may be formed between the contact-level dielectric layer 60 and the first interconnect-level dielectric layer 70. In other words, the first interconnect-level dielectric layer 70 may be formed at any interconnect level over the contact-level dielectric layer 60.

The first interconnect-level dielectric layer 70 may comprise any interconnect-level dielectric (e.g., inter-layer dielectric, ILD) material known in the art. For example, the first interconnect-level dielectric layer 70 may comprise undoped silicate glass (i.e., silicon oxide), a doped silicate glass, or porous or nonporous organosilicate glass, etc. The first interconnect-level dielectric layer 70 may be deposited by chemical vapor deposition or by spin coating. The thickness of the first interconnect-level dielectric layer 70 may be in a range from 80 nm to 400 nm, such as from 120 nm to 300 nm, although lesser and greater thicknesses may also be employed.

The first etch-stop dielectric layer 71 comprises a dielectric material that may be employed as an etch-stop material during a subsequent anisotropic etch processes. For example, the first etch-stop dielectric layer 71 may comprise a dielectric material such as silicon nitride, silicon carbonitride, silicon oxynitride, silicon oxycarbide or a dielectric metal oxide, such as aluminum oxide. The first etch-stop dielectric layer 71 may be deposited by chemical vapor deposition or atomic layer deposition. The thickness of the first etch-stop dielectric layer 71 may be in a range from 5 nm to 40 nm, such as from 10 nm to 30 nm, although lesser and greater thicknesses may also be employed.

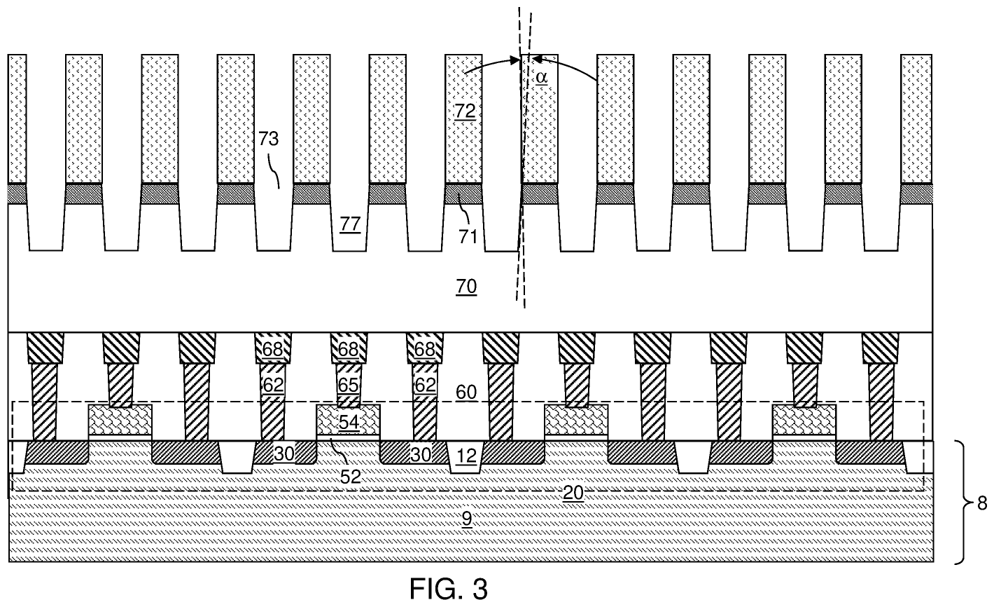

Referring to FIG. 3, a first photoresist layer 72 may be deposited over the first etch-stop dielectric layer 71, and can be lithographically patterned to form openings having a respective line pattern. As used herein, a line pattern refers to a pattern that is laterally elongated along a horizontal direction, and may optionally have a uniform width. In some embodiments, the pattern of the openings in the first photoresist layer 72 may comprise a line-and-space pattern in which elongated rectangular openings alternate with elongated gaps along a direction that is perpendicular to the direction of elongation. In some embodiments, a minimum lithographic pitch may be employed for at least to some of the openings in the first photoresist layer 72. As used herein, a minimum lithographic pitch refers to a minimum pitch that can be patterned with a single lithographic exposure step and a single development to step for a given combination of a lithographic tool and a photoresist material. In the illustrated example, the pattern of the openings in the first photoresist layer 72 comprises a line-and-space pattern that laterally extends along the first horizontal direction and has a uniform pitch, i.e., periodicity, along the second horizontal direction that is perpendicular to the first horizontal direction.

A first anisotropic etch process can be performed to transfer the pattern of the openings in the first photoresist layer 72 through the first etch-stop dielectric layer 71 and into an upper portion of the first interconnect-level dielectric layer 70. The first anisotropic etch process may comprise a first etch step that etches unmasked portions of the first etch-stop dielectric layer 71, and a second etch step that etches unmasked portions of the upper portion of the first interconnect-level dielectric layer 70. The first etch step forms first line-shaped openings 73 through the first etch-stop dielectric layer 71. The sidewalls of the first line-shaped openings 73 through the first etch-stop dielectric layer 71 may have a first taper angle a with respect to the vertical direction. The first taper angle a may be in a range from 0.5 degree to 10 degrees, such as from 1.0 degree to 4.0 degrees, although lesser and greater angles may also be employed. The second etch step forms first line cavities 77 in the upper portion of the first interconnect-level dielectric layer 70. The depth of the first line cavities 77 may be in a range from 20% to 60%, such as from 25% to 40%, of the thickness of the first interconnect-level dielectric layer 70. Generally, the first line cavities 77 can be formed in an upper portion of the first interconnect-level dielectric layer 70 by transferring the pattern of the first line-shaped openings 73 into the upper portion of the first interconnect-level dielectric layer 70. The first photoresist layer 72 can be subsequently removed, for example, by ashing.

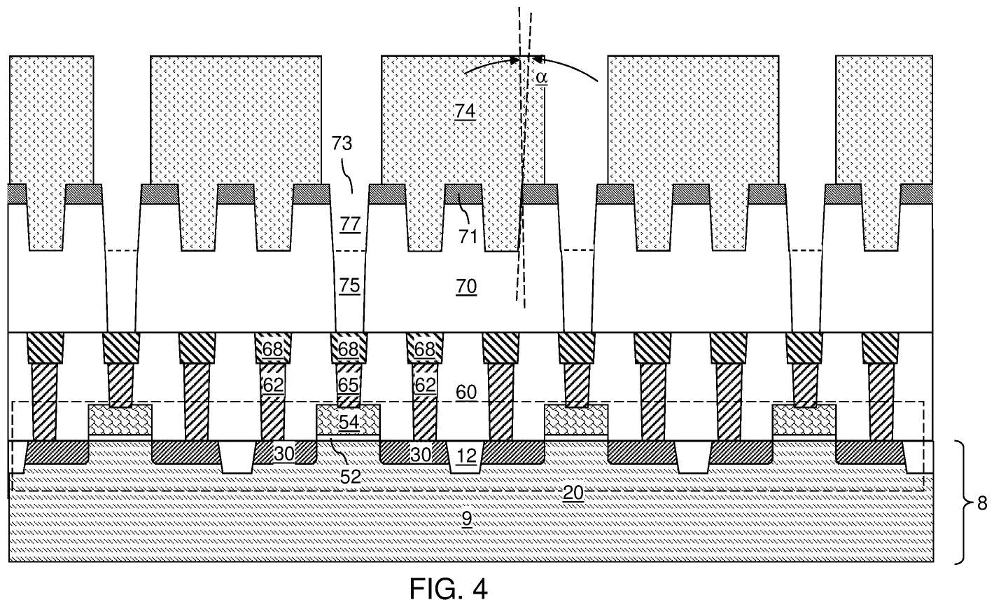

Referring to FIG. 4, a second photoresist layer 74 may be applied over the first etch-stop dielectric layer 71, and may be lithographically patterned to form a discrete openings in areas in which conductive via portions are to be subsequently formed in the first interconnect-level dielectric layer 70. Each of the discrete openings in the second photoresist layer 74 may be aligned to a respective one of the underlying first line-shaped openings 73 under the condition of an ideal alignment to the pattern of the first line-shaped openings 73. In practice, a nonzero overlay error, i.e., a nonzero difference between the actual position of a discrete opening in the second photoresist layer 74 and an ideal location of the discrete opening in the second photoresist layer 74 may exist in a plan view, such as a top-down view. Further, the actual size of the discrete openings, as measured by a maximum lateral dimension (such as a diameter), may deviate from the target size for the discrete openings due to process variations during lithographic exposure and development. In the illustrated example in FIG. 4, the discrete openings in the second photoresist layer 74 have a size is larger than the target size.

A second anisotropic etch process can be performed employing a combination of the first etch-stop dielectric layer 71 and the second photoresist layer 74 as an etch mask. The combination of the first etch-stop dielectric layer 71 and the second photoresist layer 74 defines the composite pattern that includes only overlapping areas between the areas of the first line-shaped openings 73 in the first etch-stop dielectric layer 71 and the areas of the discrete openings in the second photoresist layer 74. The etchant gases employed during the second anisotropic etch process etch only portions of the first interconnect-level dielectric layer 70 that are not masked by the etch mask, i.e., the combination of the first etch-stop dielectric layer 71 and the second photoresist layer 74. In other words, the second anisotropic etch process etches portions of the first interconnect-level dielectric layer 70 located within an area in which the discrete opening in the second photoresist layer 74 overlaps with the first line cavity 77 in a plan view from underneath the first line cavity 77.

First via cavities 75 are formed in the volumes from which the material of the first interconnect-level dielectric layer 70 is removed by the second anisotropic etch process. Each of the first via cavities 75 may be connected to a respective overlying first line cavity 77. Each contiguous combination of a first line cavity 77 and at least one first via cavity 75 constitutes a first integrated line-and-via cavity (75, 77). A top surface of an underlying conductive interconnect structure, such as a top surface of an underlying contact-level conductive line 68, may be physically exposed underneath each first via cavities 75. Thus, the first via cavities 75 are self-aligned to the first line cavities 77 due to the presence of the first etch-stop dielectric layer 71, which prevents the first via cavities 75 from being laterally offset from the respective underlying first line cavities 77. The second photoresist layer 74 may be subsequently removed, for example, by ashing.

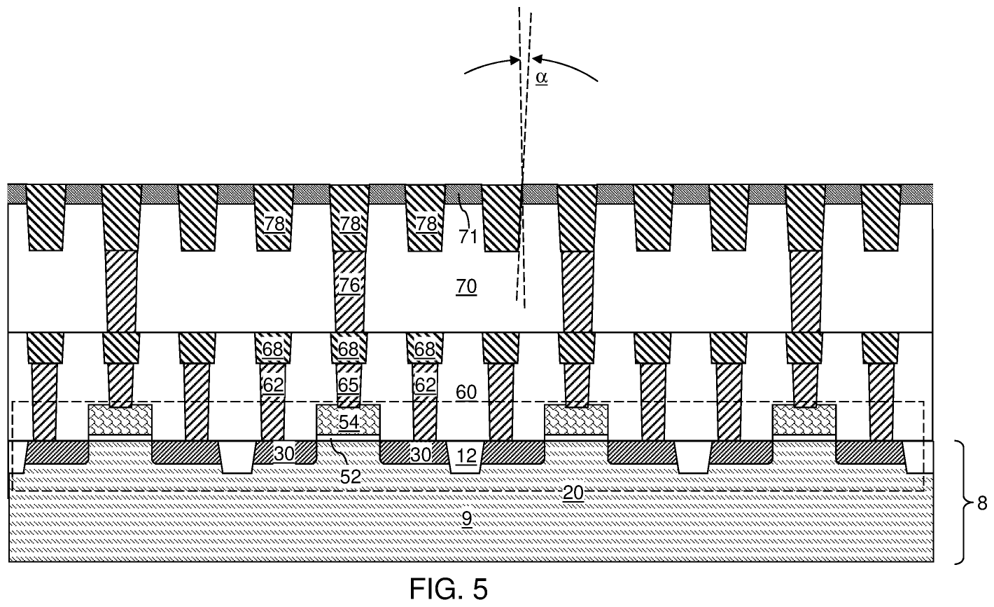

Referring to FIG. 5, at least one electrically conductive material can be formed within the first via cavities 75, the first line cavities 77, and the first line-shaped openings 73 and over the first etch-stop dielectric layer 71. The at least one electrically conductive material can be deposited within each contiguous combination of at least one first via cavity 75, a first line cavity 77, and a first line-shaped opening 73. The at least one electrically conductive material may comprise a electrically conductive barrier liner material and an electrically conductive fill material.

The electrically conductive barrier liner material may comprise a metallic nitride diffusion barrier material, such as TiN, TaN, WN, and/or MoN. The electrically conductive barrier liner material may be deposited directly on the physically exposed sidewall surfaces and the bottom surfaces of the first interconnect-level dielectric layer 70, and directly on physically exposed sidewalls and the top surface of the first etch-stop dielectric layer 71 by performing a physical vapor deposition process or a chemical vapor deposition process. The thickness of the vertically-extending portions of the at least one electrically conductive material on the sidewalls of the first via cavities 75 and the first line cavities 77 may be in a range from 1 nm to 10 nm, such as from 2 nm to 5 nm, although lesser and greater thicknesses may also be employed.

The electrically conductive fill material may comprise an electroplatable metal or metal alloy, such as Cu, Ni, Au, Ag, Sn, Pd, SnPb, Pt, etc. In one embodiment, the electrically conductive fill material may comprise Cu. Alternatively, the electrically conductive fill material may comprise a metal that can be deposited by chemical vapor deposition or physical vapor deposition. Such metals include W, Ti, Ta, Mo, Co, Ru, etc. Generally, the at least one electrically conductive material can be deposited within each void that comprises volumes of a first line-shaped opening 73 and a first line cavity 77 and optionally at least one first via cavity 75 and over the first etch-stop dielectric layer 71.

A first chemical mechanical polishing (CMP) process can be performed to remove portions of the at least one electrically conductive material from above the horizontal plane including the top surface of the first etch-stop dielectric layer 71. Each remaining portion of the at least one electrically conductive material embedded within the first interconnect-level dielectric layer 70 and the first etch-stop dielectric layer 71 comprises a first conductive interconnect structure (76, 78). Each first conductive interconnect structure (76, 78) comprises a respective first conductive line portion 78 and optionally comprises a respective set of at least one first conductive via portion 76. Each first conductive line portion 78 fills a volumes of a respective first line cavity 77 and a respective first line-shaped opening 73 in the first etch-stop dielectric layer 71. Each first conductive via portion 76 fills a volume of a respective first via cavity 75. Each first conductive via portion 76 of the first conductive interconnect structure (76, 78) comprises a respective bottom surface segment that contacts a top surfaces of a respective underlying conductive interconnect structure, such as a top surface of a respective one of the contact-level conductive lines 68. The top surface of each first conductive interconnect structure (76, 78) may be formed within the horizontal plane including the top surface of the first etch-stop dielectric layer 71 after the first CMP process.

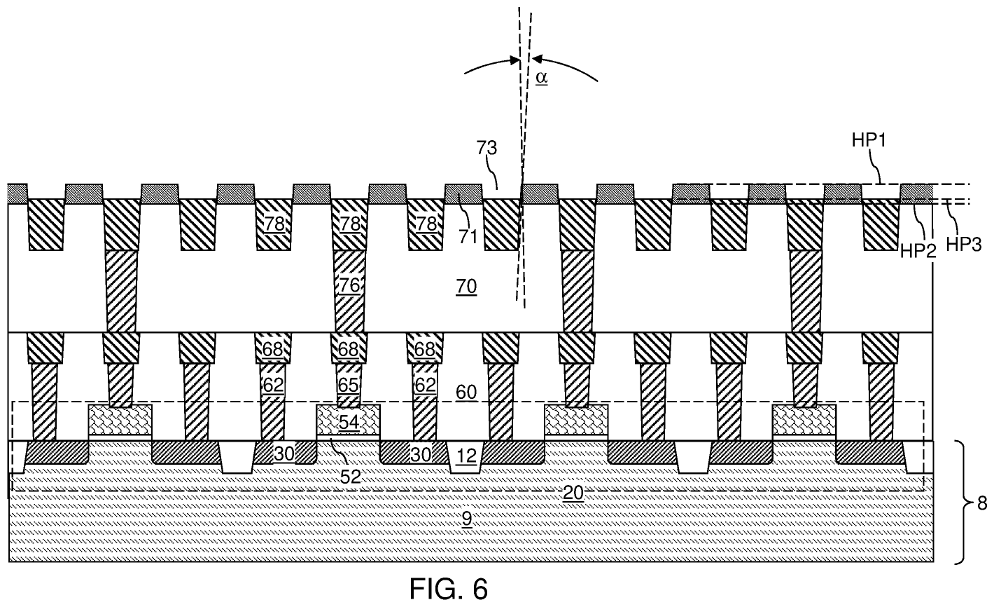

Referring to FIG. 6, top surfaces of the first conductive interconnect structure (76, 78) can be vertically recessed selective to the dielectric material of the first etch-stop dielectric layer 71 by performing a selective recess etch process. In one embodiment, a wet etch process may be employed to vertically recess the first conductive interconnect structure (76, 78) selective to the dielectric material of the first etch-stop dielectric layer 71. In an illustrative example, the wet etch process may employ a solution of ammonium persulfate {(NH₄)₂S₂O₈} as the etchant. Alternatively, a reactive ion etch process may be employed to vertically recess the first conductive interconnect structures (76, 78). In an illustrative example, the reactive ion etch process may employ a mixture of chlorine (Cl₂) and boron trichloride (BCl₃) as etchant gases.

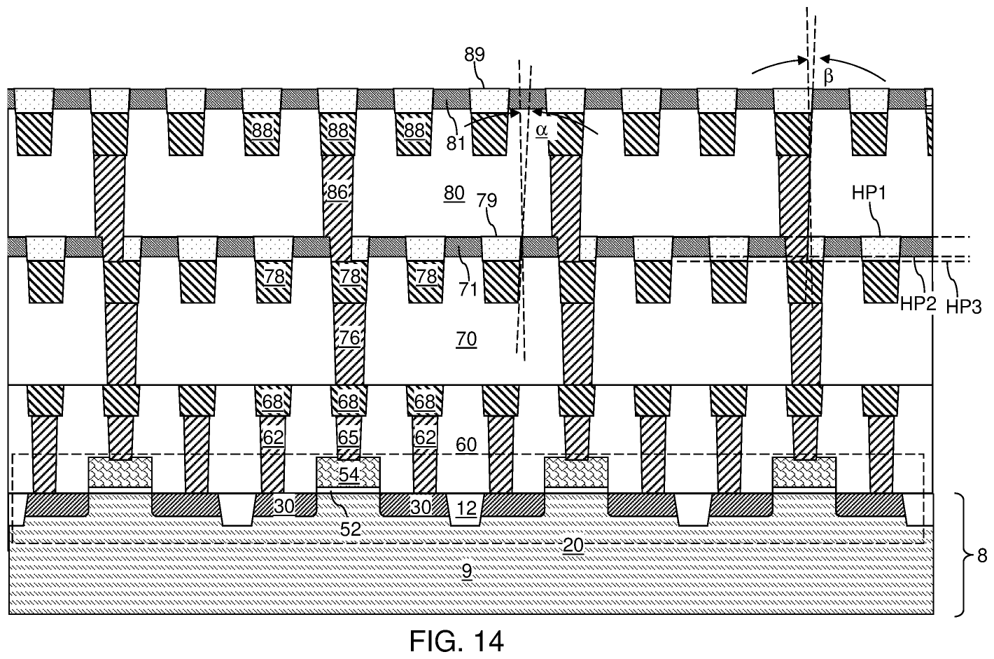

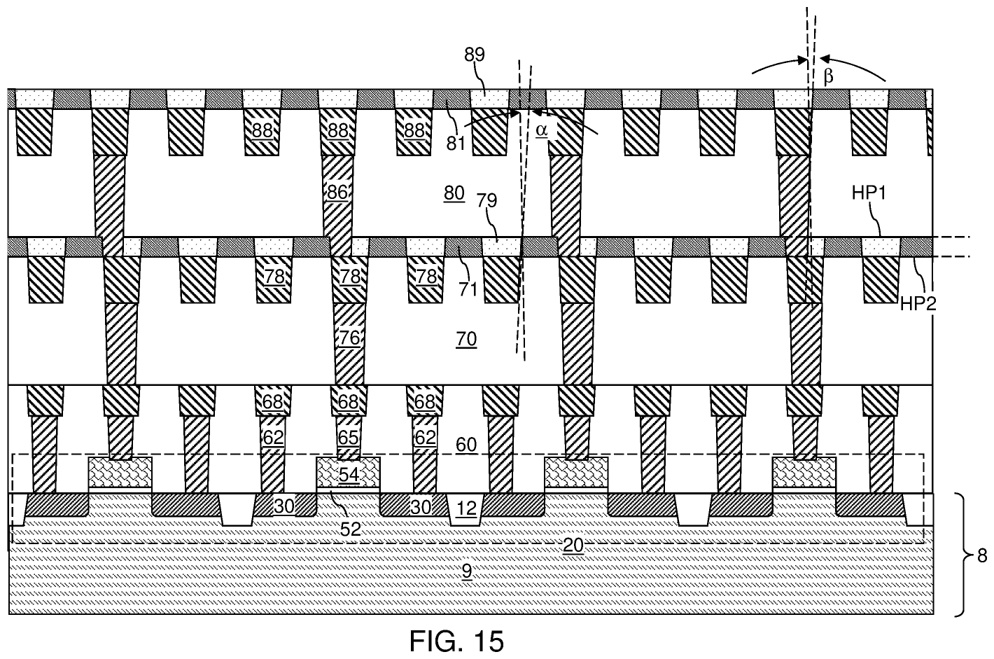

Generally, the at least one electrically conductive material of the first conductive interconnect structures (76, 78) can be vertically recessed by performing a selective etch process that is selective to the material of the first etch-stop dielectric layer 71 after the first chemical mechanical polishing process. In one embodiment, the top surface of the first etch-stop dielectric layer 71 can be located within a first horizontal plane HP1, and the interface between a bottom surface of the first etch-stop dielectric layer 71 and a top surface of the first interconnect-level dielectric layer 70 can be located within a second horizontal plane HP2 which is vertically offset from the first horizontal plane HP1 by the thickness of the first etch-stop dielectric layer 71. The top surfaces of the first conductive interconnect structures (76, 78) after the selective recess process may be located within a third horizontal plane HP3 which underlies the first horizontal plane HP1. The third horizontal plane HP3 may overlie the second horizontal plane HP2, as shown in FIG. 6, may underlie the second horizontal plane HP2, as shown in FIG. 14 and described below, or may coincide with the second horizontal plane HP2, as shown in FIG. 15 and described below, depending on the depth of the recesses that are formed above the first conductive interconnect structures (76, 78). Generally, the at least one electrically conductive material of the first conductive interconnect structures (76, 78) can be removed from above the first horizontal plane HP1 such that each remaining portion of the first conductive interconnect structures (76, 78) has a top surface located within the third horizontal plane HP3. In one embodiment, an entirely of each first conductive interconnect structure (76, 78) may be located below the first horizontal plane HP1.

In one embodiment shown in FIGS. 6 and 14, a horizontal plane including an interface between a bottom surface of the first etch-stop dielectric layer 71 and a top surface of the first interconnect-level dielectric layer 70, i.e., the second horizontal plane HP2, is vertically offset from the horizontal plane including the top surface of the first conductive line portion 78, i.e., the third horizontal plane HP3.

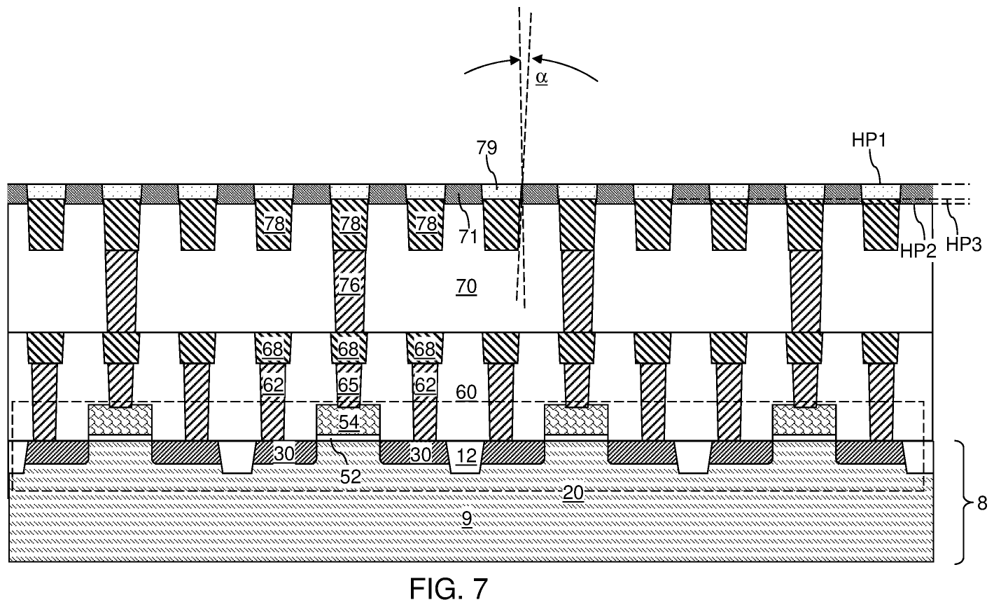

Referring to FIG. 7, a dielectric fill material that is different from the material of the first etch-stop dielectric layer 71 can be deposited within the volumes of the first line-shaped openings 73 that overlie the first conductive interconnect structures (76, 78). The dielectric fill material comprises a planarizable material, i.e., a material that can be subsequently planarized, for example, by performing a chemical mechanical polishing process. Further, the dielectric fill material can be selected such that the dielectric fill material provides lower etch resistance during a subsequent anisotropic etch process that forms via cavities employing the first etch-stop dielectric layer 71 as an etch-stop layer. In other words, the dielectric fill material is selected such that a subsequent anisotropic etch process can etch the dielectric fill material at a higher rate than the first etch-stop dielectric layer 71. Thus, the dielectric fill material can be selected based on the material of the first etch-stop dielectric layer 71. The dielectric fill material may comprise, for example, undoped silicate glass (i.e., silicon oxide), a doped silicate glass, or organosilicate glass.

A second chemical mechanical polishing process can be performed to remove portions of the deposited dielectric fill material from above the first horizontal plane HP1, i.e., from above the horizontal plane including the top surfaces of the first etch-stop dielectric layer 71. Remaining portions of the dielectric fill material filling a respective one of the first line-shaped openings 73 in the first etch-stop dielectric layer 71 constitute first complementary dielectric fill material portions 79. The first complementary dielectric fill material portions 79 may have a different material composition from, or may have the same material composition as, the first interconnect-level dielectric layer 70 and a second interconnect-level dielectric layer to be subsequently formed thereupon. Generally, the first complementary dielectric fill material portions 79 may be formed by depositing a dielectric fill material over the top surfaces of the first conductive interconnect structures (76, 78) and over the first etch-stop dielectric layer 71, and by removing portions of the dielectric fill material from above the horizontal plane including the top surface of the first etch-stop dielectric layer 71.

Top surfaces of the first complementary dielectric fill material portions 79 may be formed in the same horizontal plane HP1 as the top surface of the first etch-stop dielectric layer 71. In one embodiment, a first complementary dielectric fill material portion 79 filling a first line-shaped opening 73 may have a pair of bottom edges that coincide with a pair of edges of a top surface of the first conductive line portion 78 of an underlying first conductive interconnect structure (76, 78). In one embodiment, the pair of bottom edges of the first complementary dielectric fill material portion 79 laterally extend along a first horizontal direction with a uniform lateral spacing therebetween. In one embodiment, the first conductive interconnect structure (76, 78) may comprise an integrated line-and-via structure that comprises a first conductive via portion 76 that is adjoined to a bottom end of the first conductive line portion 78. In one embodiment, the width of a topmost portion of the first conductive via portion 76 along a second horizontal direction that is perpendicular to the first horizontal direction may be the same as the width of a bottommost portion of the first conductive line portion 78 along the second horizontal direction, and may be less than the uniform lateral spacing.

In one embodiment, a horizontal plane including the pair of bottom edges of the first complementary dielectric fill material portion 79 and the pair of edges of the top surface of the first conductive line portion 78 (i.e., the third horizontal plane HP3) is located above a horizontal plane including an interface between a bottom surface of the first etch-stop dielectric layer 71 and a top surface of the first interconnect-level dielectric layer 70 (i.e., the second horizontal plane HP2).

In another embodiment shown in FIG. 14, a horizontal plane including the pair of bottom edges of the first complementary dielectric fill material portion 79 and the pair of edges of the top surface of the first conductive line portion 78 (i.e., the third horizontal plane HP3) is located below a horizontal plane including an interface between a bottom surface of the first etch-stop dielectric layer 71 and a top surface of the first interconnect-level dielectric layer 70 (i.e., the second horizontal plane HP2).

In another embodiment shown in FIG. 15, the pair of bottom edges of the first complementary dielectric fill material portion 79 and the pair of edges of the top surface of the first conductive line portion 78 are located within a horizontal plane including an interface between a bottom surface of the first etch-stop dielectric layer 71 and a top surface of the first interconnect-level dielectric layer 70 (i.e., the second horizontal plane HP2).

In one embodiment, the entirety of a top surface of the first complementary dielectric fill material portion 79 may be located within a horizontal plane including a top surface of the first etch-stop dielectric layer 71. The thickness of the first complementary dielectric fill material portion 79 may be different from, or may be the same as, the thickness of the first etch-stop dielectric layer 71.

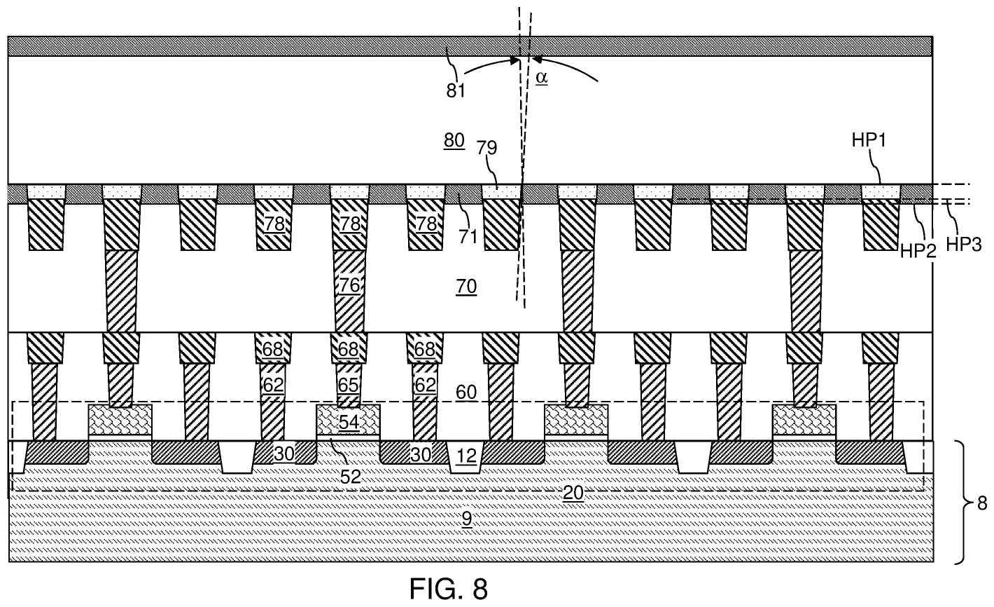

Referring to FIG. 8, a second interconnect-level dielectric layer 80 and a second etch-stop dielectric layer 81 can be formed over the first etch-stop dielectric layer 71 and the first complementary dielectric fill material portions 79. The second interconnect-level dielectric layer 80 may comprise any interconnect-level dielectric material known in the art that is different from the material of the first etch-stop dielectric layer 71. For example, the second interconnect-level dielectric layer 80 may comprise undoped silicate glass, a doped silicate glass, or porous or nonporous organosilicate glass, etc. The material of the second interconnect-level dielectric layer 80 may be different from, or may be the same as, the material of the first complementary dielectric fill material portions 79 and the material of the first interconnect-level dielectric layer 70. The second interconnect-level dielectric layer 80 may be deposited by chemical vapor deposition or by spin coating. The thickness of the second interconnect-level dielectric layer 80 may be in a range from 80 nm to 400 nm, such as from 120 nm to 300 nm, although lesser and greater thicknesses may also be employed.

The second etch-stop dielectric layer 81 comprises a dielectric material that may be employed as an etch-stop material during a subsequent anisotropic etch process. For example, the second etch-stop dielectric layer 81 may comprise a dielectric material such as silicon nitride, silicon carbonitride, silicon oxynitride, silicon oxycarbide or a dielectric metal oxide, such as aluminum oxide. The second etch-stop dielectric layer 81 material may be the same as or different from the material of the first etch-stop dielectric layer 71. The second etch-stop dielectric layer 81 may be deposited by chemical vapor deposition or atomic layer deposition. The thickness of the second etch-stop dielectric layer 81 may be in a range from 5 nm to 40 nm, such as from 10 nm to 30 nm, although lesser and greater thicknesses may also be employed.

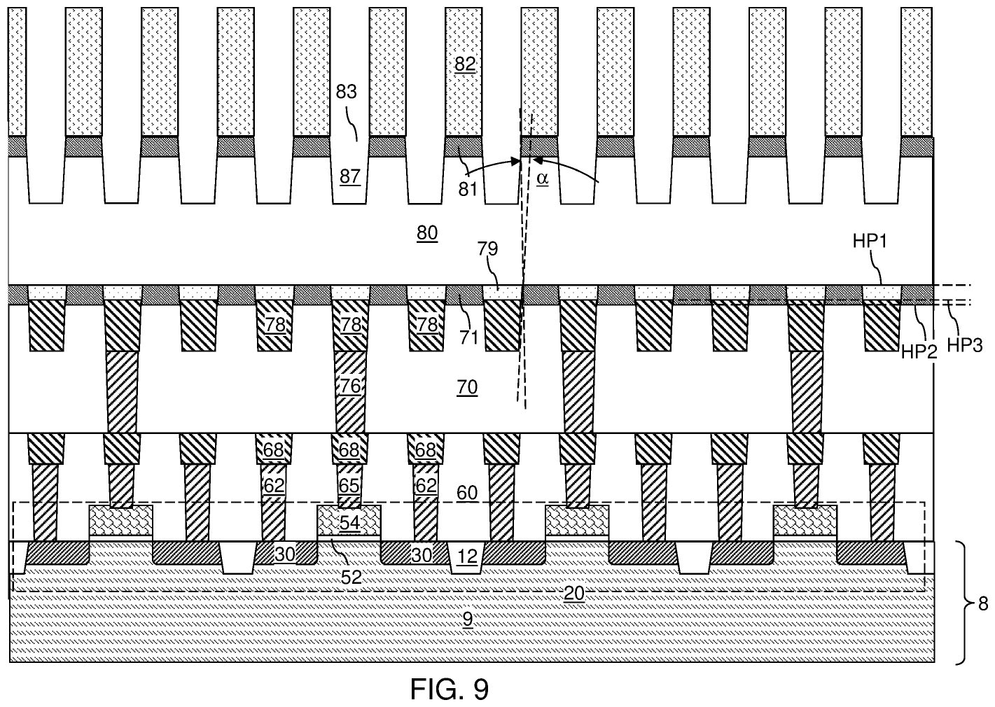

Referring to FIG. 9, a third photoresist layer 82 may be deposited over the second etch-stop dielectric layer 81, and can be lithographically patterned to form openings having a respective line pattern. In some embodiments, the pattern of the openings in the third photoresist layer 82 may comprise a line-and-space pattern in which elongated rectangular openings alternate with elongated gaps along a direction that is perpendicular to the direction of elongation. In some embodiments, a minimum lithographic pitch may be employed for at least to some of the openings in the third photoresist layer 82.

A third anisotropic etch process can be performed to transfer the pattern of the openings in the third photoresist layer 82 through the second etch-stop dielectric layer 81 and into an upper portion of the second interconnect-level dielectric layer 80. The third anisotropic etch process may comprise a first etch step that etches unmasked portions of the second etch-stop dielectric layer 81, and a second etch step that etches unmasked portions of the upper portion of the second interconnect-level dielectric layer 80. The first etch step forms second line-shaped openings 83 through the second etch-stop dielectric layer 81. The sidewalls of the second line-shaped openings 83 through the second etch-stop dielectric layer 81 may have a taper angle with respect to the vertical direction. The taper angle may be in a range from 0.5 degree to 10 degrees, such as from 1.0 degree to 4.0 degrees. The second etch step forms second line cavities 87 in the upper portion of the second interconnect-level dielectric layer 80. The depth of the second line cavities 87 may be in a range from 20% to 60%, such as from 25% to 40%, of the thickness of the second interconnect-level dielectric layer 80. Generally, the second line cavities 87 can be formed in an upper portion of the second interconnect-level dielectric layer 80 by transferring the pattern of the second line-shaped openings 83 into the upper portion of the second interconnect-level dielectric layer 80. The third photoresist layer 82 can be subsequently removed, for example, by ashing.

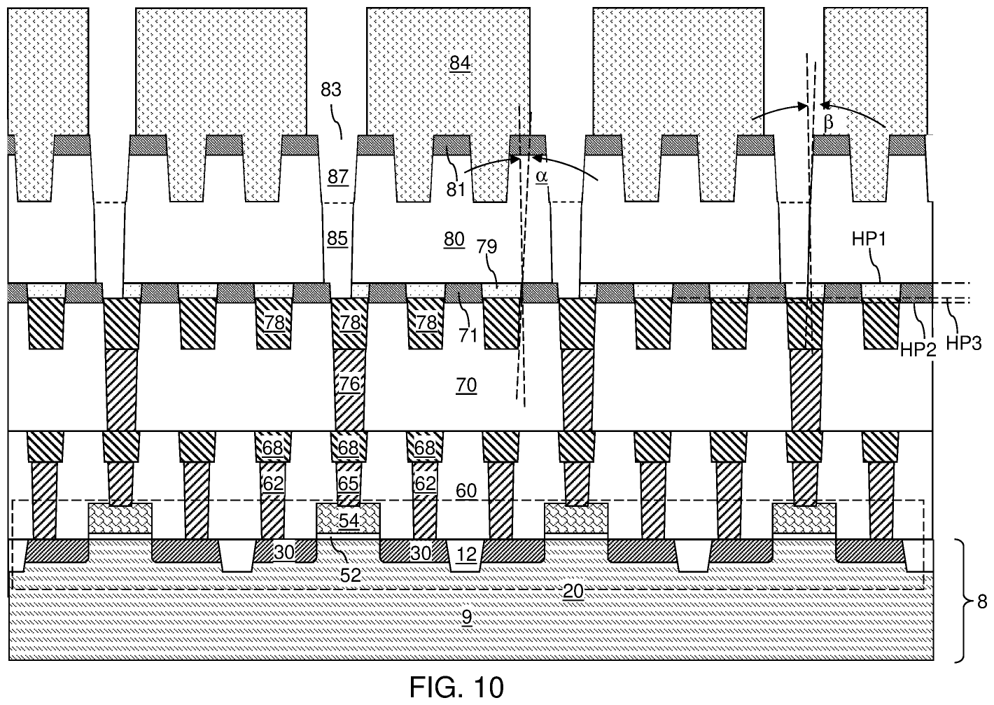

Referring to FIG. 10, a fourth photoresist layer 84 may be applied over the second etch-stop dielectric layer 81, and may be lithographically patterned to form a discrete openings in areas in which conductive via portions are to be subsequently formed in the second interconnect-level dielectric layer 80. Each of the discrete openings in the fourth photoresist layer 84 may be aligned to a respective one of the underlying second line-shaped openings 83 under the condition of an ideal alignment to the pattern of the second line-shaped openings 83. In practice, a nonzero overlay error, i.e., a nonzero difference between the actual position of a discrete opening in the fourth photoresist layer 84 and an ideal location of the discrete opening in the fourth photoresist layer 84 may exist in a plan view, such as a top-down view. Further, the actual size of the discrete openings, as measured by a maximum lateral dimension (such as a diameter), may deviate from the target size for the discrete openings due to process variations during lithographic exposure and development. In the illustrated example in FIG. 4, the discrete openings in the fourth photoresist layer 84 have a size is larger than the target size.

A fourth anisotropic etch process can be performed employing a combination of the second etch-stop dielectric layer 81 and the fourth photoresist layer 84 as an etch mask. The combination of the second etch-stop dielectric layer 81 and the fourth photoresist layer 84 defines the composite pattern that includes only overlapping areas between the areas of the second line-shaped openings 83 in the second etch-stop dielectric layer 81 and the areas of the discrete openings in the fourth photoresist layer 84. The etchant gases employed during the fourth anisotropic etch process etches only portions of the second interconnect-level dielectric layer 80 that are not masked by the etch mask, i.e., the combination of the second etch-stop dielectric layer 81 and the fourth photoresist layer 84. In other words, the fourth anisotropic etch process etches portions of the second interconnect-level dielectric layer 80 located within an area in which the discrete opening in the fourth photoresist layer 84 overlaps with the second line cavity 87 in a plan view from underneath the second line cavity 87.

Second via cavities 85 are formed in the volumes from which the material of the second interconnect-level dielectric layer 80 is removed by the fourth anisotropic etch process. Each of the second via cavities 85 may be connected to a respective overlying second line cavity 87. Each contiguous combination of a second line cavity 87 and at least one second via cavity 85 constitutes a second integrated line-and-via cavity (85, 87). According to an aspect of the present disclosure, the fourth anisotropic etch process can etch the material of the second interconnect-level dielectric layer 80 and the material of the first complementary dielectric fill material portions 79 selective to the materials of the first etch-stop dielectric layer 71 and the first conductive interconnect structures (76, 78). Generally, a second via cavity 85 can be formed through the second interconnect-level dielectric layer 80 within an area that is located entirely within an area of the opening in the second etch-stop dielectric layer 81 by performing the fourth anisotropic etch process.

A top surface of an underlying conductive interconnect structure, such as a top surface of an underlying first conductive interconnect structures (76, 78), may be physically exposed underneath each second via cavities 85. In one embodiment, the first etch-stop dielectric layer 71 may be physically exposed to at least one of the second via cavities 85. In one embodiment, surfaces of a second via cavity 85 may comprise a first tapered sidewall segment of the first etch-stop dielectric layer 71 having a first taper angle a relative to a vertical direction. In addition, each second via cavity 85 may be laterally bounded by a respective sidewall the second interconnect-level dielectric layer 80 which has a second taper angle b relative to the vertical direction that is different from the first taper angle a. Each of the second via cavities 85 may have a bottom portion to which a surface segment of a respective first complementary dielectric fill material portion 79 is exposed. One or more of the second via cavities 85 may overlie a respective physically exposed surface segment of the top surface of the first etch-stop dielectric layer 71. In this case, such second via cavities 85 may have a stepped vertical cross-sectional profile that includes a first horizontal surface segment that is a surface segment of an underlying first conductive interconnect structure (76, 78), a second horizontal surface segment that is a surface segment of a top surface of the first etch-stop dielectric layer 71, and a first tapered surface segment that is a segment of a sidewall of the first etch-stop dielectric layer 71. The first tapered sidewall segment connects the first bottom surface segment and the second bottom surface segment. The fourth photoresist layer 84 may be subsequently removed, for example, by ashing.

The sidewalls of the second via cavities 85 may be tapered, and may have a second taper angle b with respect to the vertical direction. The second taper angle b may be different from the first taper angle a. The second taper angle b may be in a range from 0.2 degree to 8 degrees, such as from 0.7 degree to 3.0 degrees, although lesser and greater angles may also be employed. In one embodiment, a sidewall of a second via cavity 85 may have a first tapered sidewall segment having the first taper angle a, a second tapered sidewall segment which is a sidewall of the second interconnect-level dielectric layer 80 and having the second taper angle b, and a connecting horizontal surface segment that is a segment of a top surface of the first etch-stop dielectric layer 71.

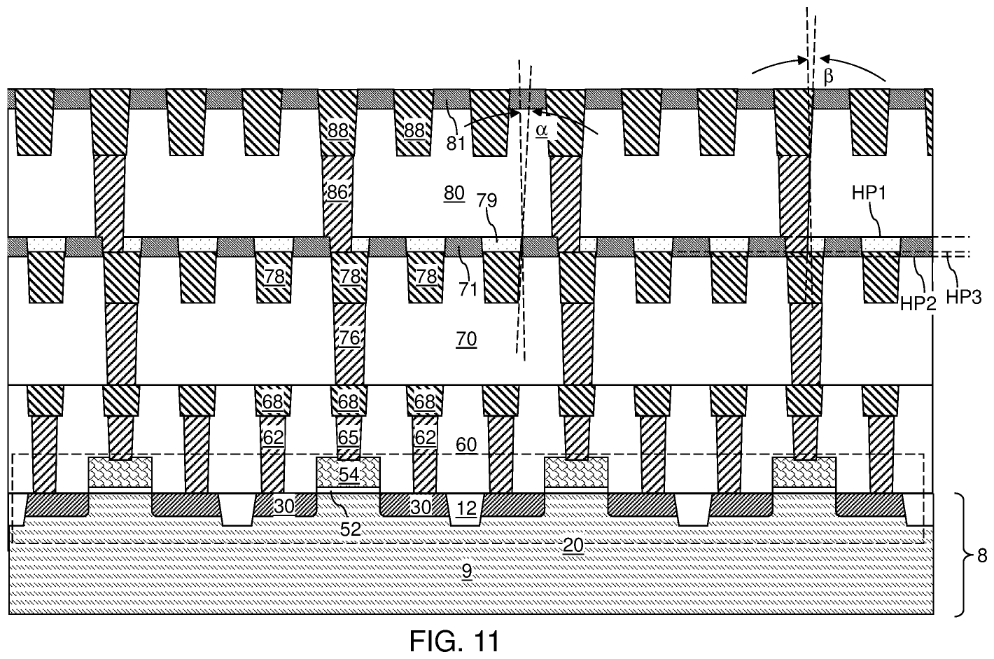

Referring to FIG. 11, at least one electrically conductive material can be formed within the second via cavities 85, the second line cavities 87, and the second line-shaped openings 83 and over the second etch-stop dielectric layer 81. The at least one electrically conductive material can be deposited within each contiguous combination of at least one second via cavity 85, a second line cavity 87, and a second line-shaped opening 83. The at least one electrically conductive material may comprise an electrically conductive barrier liner material and an electrically conductive fill material.

The electrically conductive barrier liner material may comprise a metallic nitride barrier material such as TiN, TaN, WN, and/or MoN. The electrically conductive barrier liner material may be deposited directly on the physically exposed sidewall surfaces and the bottom surfaces of the second interconnect-level dielectric layer 80, and directly on physically exposed sidewalls and the top surface of the second etch-stop dielectric layer 81 by performing a physical vapor deposition process or a chemical vapor deposition process. The thickness of the vertically-extending portions of the at least one electrically conductive material on the sidewalls of the second via cavities 85 and the second line cavities 87 may be in a range from 1 nm to 10 nm, such as from 2 nm to 5 nm, although lesser and greater thicknesses may also be employed.

The electrically conductive fill material may comprise an electroplatable metal or metal alloy, such as Cu, Ni, Au, Ag, Sn, Pd, SnPb, Pt, etc. In one embodiment, the electrically conductive fill material may comprise Cu. Alternatively, the electrically conductive fill material may comprise a metal that can be deposited by chemical vapor deposition or physical vapor deposition. Such metals include W, Ti, Ta, Mo, Co, Ru, etc. Generally, the at least one electrically conductive material can be deposited within each void that comprises volumes of a second line-shaped opening 83 and a second line cavity 87 and optionally at least one second via cavity 85 and over the second etch-stop dielectric layer 81.

A third chemical mechanical polishing (CMP) process can be performed to remove portions of the at least one electrically conductive material from above the horizontal plane including the top surface of the second etch-stop dielectric layer 81. Each remaining portion of the at least one electrically conductive material embedded within the second interconnect-level dielectric layer 80 and the second etch-stop dielectric layer 81 comprises a second conductive interconnect structure (86, 88). Each second conductive interconnect structure (86, 88) comprises a respective second conductive line portion 88 and optionally comprises a respective set of at least one second conductive via portion 86. Each second conductive line portion 88 fills a volumes of a respective second line cavity 87 and a respective second line-shaped opening 83 in the second etch-stop dielectric layer 81. Each second conductive via portion 86 fills a volume of a respective second via cavity 85. Each second conductive via portion 86 of the second conductive interconnect structure (86, 88) comprises a respective bottom surface segment that contacts a top surfaces of a respective underlying conductive interconnect structure such as a top surface of a respective one of the first conductive interconnect structures (76, 78). The top surface of each second conductive interconnect structure (86, 88) may be formed within the horizontal plane including the top surface of the second etch-stop dielectric layer 81 after the third CMP process.

In one embodiment, a conductive via portion 86 of a second conductive interconnect structure (86, 88) comprises a first bottom surface segment that contacts a top surface of a first conductive line portion 78 of the first conductive interconnect structure (76, 78), and a second bottom surface segment that contacts a segment of a top surface of the first etch-stop dielectric layer 71. In one embodiment, the conductive via portion 86 of the second conductive interconnect structure (86, 88) comprises a first tapered sidewall segment that connects the first bottom surface segment and the second bottom surface segment and contacts a segment of a sidewall of the first etch-stop dielectric layer 71. In one embodiment, the first tapered sidewall segment of the conductive via portion 86 of the second conductive interconnect structure (86, 88) has a first taper angle a relative to a vertical direction, and a sidewall of the conductive via portion 86 of the second conductive interconnect structure (86, 88) in contact with the second interconnect-level dielectric layer 80 has a second taper angle b relative to the vertical direction that is different from the first taper angle a.

In one embodiment, a lower portion of the conductive via portion 86 of a second conductive interconnect structure (86, 88) may be in contact with a surface segment of a first complementary dielectric fill material portion 79. In one embodiment, at least a subset of the second conductive interconnect structure (86, 88) may comprise an integrated line-and-via structure that comprises a second conductive line portion that is adjoined to an upper end of the conductive via portion 86 of the second conductive interconnect structure (86, 88).

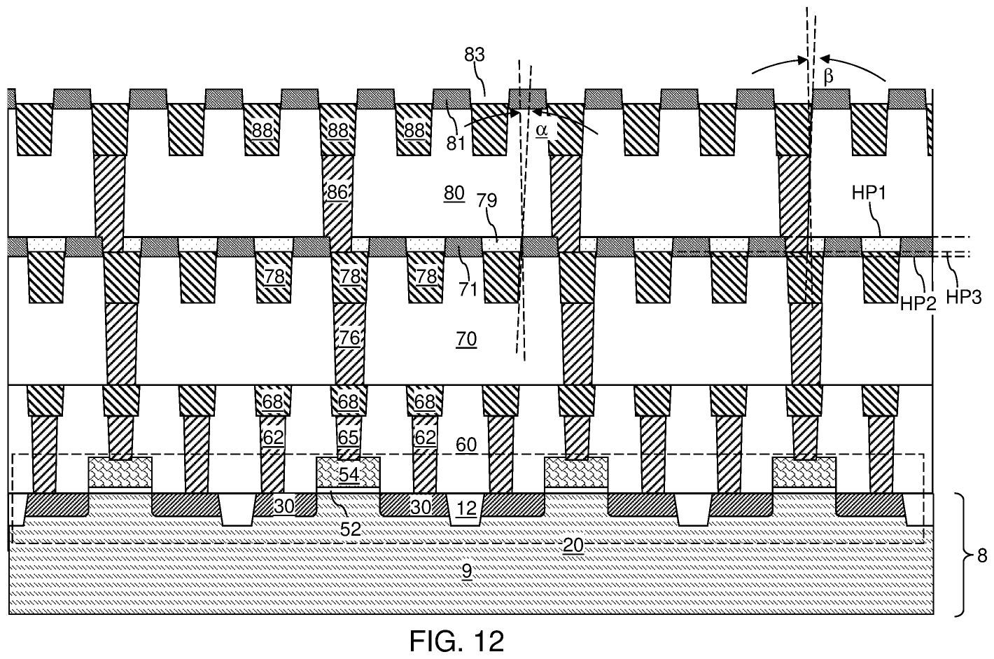

Referring to FIG. 12, top surfaces of the second conductive interconnect structure (86, 88) can be vertically recessed selective to the dielectric material of the second etch-stop dielectric layer 81 by performing a selective recess process. In one embodiment, a wet etch process may be employed to vertically recess the second conductive interconnect structure (86, 88) selective to the dielectric material of the second etch-stop dielectric layer 81. In an illustrative example, the wet etch process may employ a solution of ammonium persulfate {(NH₄)₂S₂O₈} as the etchant. Alternatively, a reactive ion etch process may be employed to vertically recess the second conductive interconnect structures (86, 88). In an illustrative example, the reactive ion etch process may employ a mixture of chlorine (Cl₂) and boron trichloride (BCl₃) as etchant gases.

Generally, the at least one electrically conductive material of the second conductive interconnect structures (86, 88) can be vertically recessed by performing a selective etch process that is selective to the material of the second etch-stop dielectric layer 81 after the third chemical mechanical polishing process. The top surfaces of the second conductive interconnect structures (86, 88) after the selective recess process may be located within a horizontal plane that may overlie, underlie, or coincide with, a horizontal plane including the interface between a bottom surface of the second etch-stop dielectric layer 81 and a top surface of the second interconnect-level dielectric layer 80 depending on the depth of the recesses that are formed above the second conductive interconnect structures (86, 88).

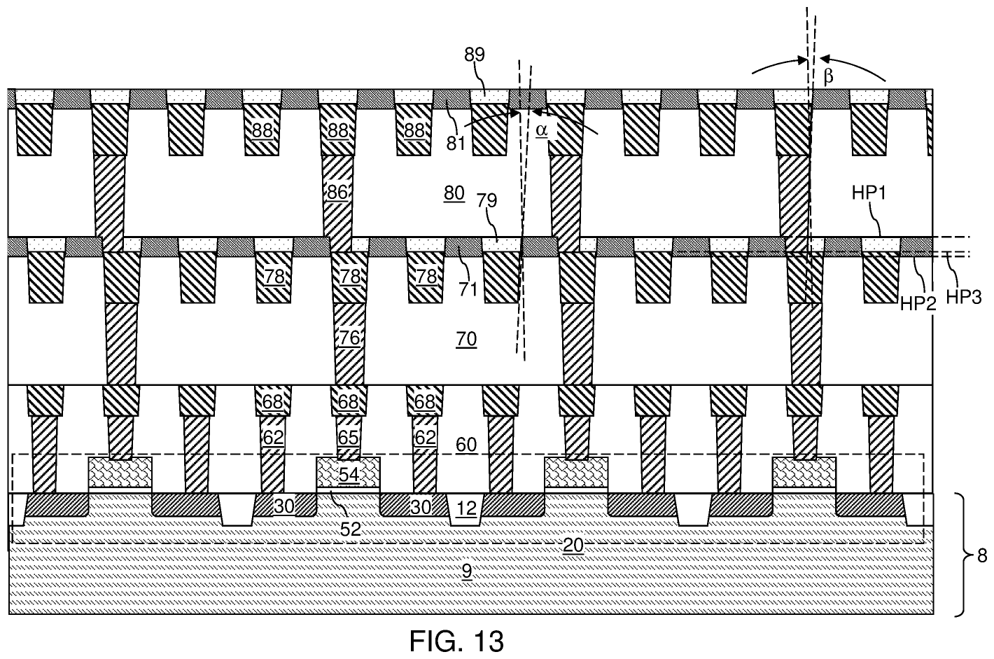

Referring to FIG. 13, a dielectric fill material that is different from the material of the second etch-stop dielectric layer 81 can be deposited within the volumes of the second line-shaped openings 83 that overlie the second conductive interconnect structures (86, 88). The dielectric fill material comprises a planarizable material, i.e., a material that can be subsequently planarized, for example, by performing a chemical mechanical polishing process. Further, the dielectric fill material can be selected such that the dielectric fill material provides lower etch resistance during a subsequent anisotropic etch process employing the second etch-stop dielectric layer 81 as an etch-stop layer. Thus, the dielectric fill material can be selected based on the material of the second etch-stop dielectric layer 81. The dielectric fill material may comprise, for example, undoped silicate glass, a doped silicate glass, or organosilicate glass.

A fourth chemical mechanical polishing process can be performed to remove portions of the deposited dielectric fill material from above the horizontal plane including the top surfaces of the second etch-stop dielectric layer 81. Remaining portions of the dielectric fill material filling a respective one of the second line-shaped openings 83 in the second etch-stop dielectric layer 81 constitute second complementary dielectric fill material portions 89. In one embodiment, the second complementary dielectric fill material portions 89 may have the same or different material composition than a fourth interconnect-level dielectric layer to be subsequently formed thereupon. Generally, the second complementary dielectric fill material portions 89 may be formed by depositing a dielectric fill material over the top surfaces of the second conductive interconnect structures (86, 88) and over the second etch-stop dielectric layer 81, and by removing portions of the dielectric fill material from above the horizontal plane including the top surface of the second etch-stop dielectric layer 81.

Top surfaces of the second complementary dielectric fill material portions 89 may be formed in the same horizontal plane as the top surface of the second etch-stop dielectric layer 81. In one embodiment, the second complementary dielectric fill material portion 89 filling a second line-shaped opening 83 may have a pair of bottom edges that coincide with a pair of edges of a top surface of the second conductive line portion 88 of an underlying second conductive interconnect structure (86, 88). In one embodiment, the pair of bottom edges of the second complementary dielectric fill material portion 89 laterally extend along a second horizontal direction with a uniform lateral spacing therebetween. In one embodiment, the second conductive interconnect structure (86, 88) may comprise an integrated line-and-via structure that comprises a second conductive via portion 86 that is adjoined to a bottom end of the second conductive line portion 88. In one embodiment, the width of a topmost portion of the second conductive via portion 86 along a fourth horizontal direction that is perpendicular to the second horizontal direction may be the same as the width of a bottommost portion of the second conductive line portion 88 along the fourth horizontal direction, and may be less than the uniform lateral spacing.

In one embodiment, a horizontal plane including the pair of bottom edges of the second complementary dielectric fill material portion 89 and the pair of edges of the top surface of the second conductive line portion 88 is located above a horizontal plane including an interface between a bottom surface of the second etch-stop dielectric layer 81 and a top surface of the second interconnect-level dielectric layer 80.

In one embodiment, a horizontal plane including the pair of bottom edges of the second complementary dielectric fill material portion 89 and the pair of edges of the top surface of the second conductive line portion 88 is located below a horizontal plane including an interface between a bottom surface of the second etch-stop dielectric layer 81 and a top surface of the second interconnect-level dielectric layer 80.

In one embodiment, the pair of bottom edges of the second complementary dielectric fill material portion 89 and the pair of edges of the top surface of the second conductive line portion 88 are located within a horizontal plane including an interface between a bottom surface of the second etch-stop dielectric layer 81 and a top surface of the second interconnect-level dielectric layer 80.

In one embodiment, the entirety of a top surface of the second complementary dielectric fill material portion 89 may be located within a horizontal plane including a top surface of the second etch-stop dielectric layer 81. The thickness of the second complementary dielectric fill material portion 89 may be different from or may be the same as the thickness of the second etch-stop dielectric layer 81.

Referring to FIG. 14, a first alternative configuration of the exemplary structure is illustrated. In the first alternative configuration, the first complementary dielectric fill material portions 79 may be thicker than the first etch-stop dielectric layer 71, and the second complementary dielectric fill material portion 89 may be thicker than the second etch-stop dielectric layer 81. The top surface of the first etch-stop dielectric layer 71 can be located within a first horizontal plane HP1, and the interface between a bottom surface of the first etch-stop dielectric layer 71 and a top surface of the first interconnect-level dielectric layer 70 can be located within a second horizontal plane HP2 which is vertically offset from the first horizontal plane HP1 by the thickness of the first etch-stop dielectric layer 71. The top surfaces of the first conductive interconnect structures (76, 78) may be located within a third horizontal plane HP3 which underlies the second horizontal plane HP2.

Referring to FIG. 15, a second alternative configuration of the exemplary structure is illustrated. In the second alternative configuration, the first complementary dielectric fill material portions 79 may have the same thickness as the first etch-stop dielectric layer 71, and the second complementary dielectric fill material portion 89 may have the same thickness as the second etch-stop dielectric layer 81. The top surface of the first etch-stop dielectric layer 71 can be located within a first horizontal plane HP1, and the interface between a bottom surface of the first etch-stop dielectric layer 71 and a top surface of the first interconnect-level dielectric layer 70 can be located within a second horizontal plane HP2 which is vertically offset from the first horizontal plane HP1 by the thickness of the first etch-stop dielectric layer 71. The top surfaces of the first conductive interconnect structures (76, 78) may be located within the second horizontal plane HP2 (i.e., the second and the third horizontal planes comprise the same plane).

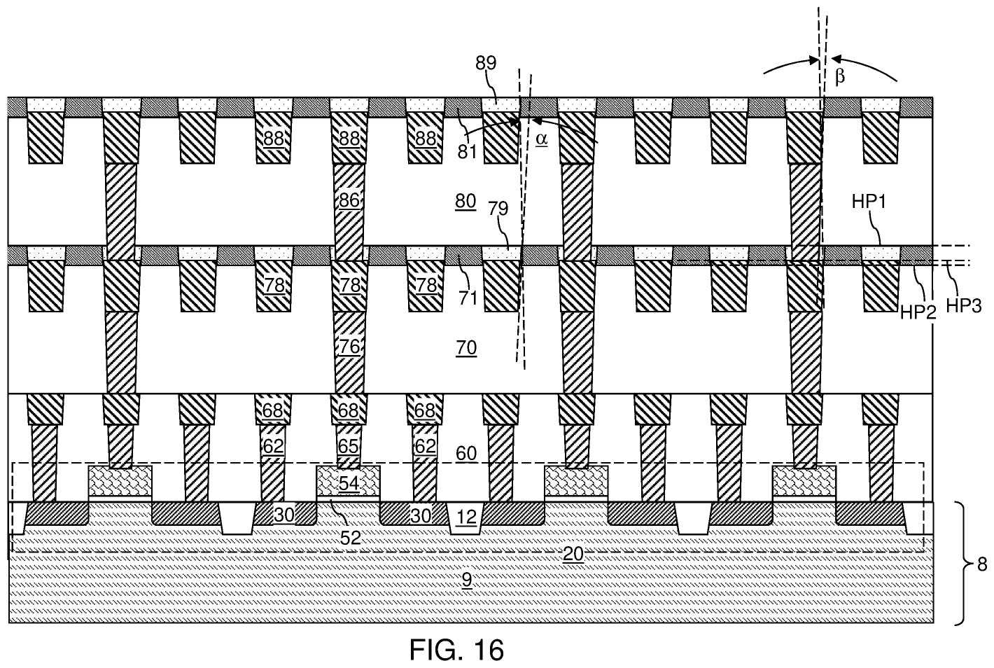

Referring to FIG. 16, a third alternative configuration of the exemplary structure according to an embodiment of the present disclosure is illustrated, which may be derived from any of the previously described configurations by reducing the overlay error between the pattern of the second via cavities 85 and the pattern of the first line cavities 77 to a level that forms the second conductive via portions 86 that do not directly contact the first etch-stop dielectric layer 71. It is understood that the overlay error between the pattern of the second via cavities 85 and the pattern of the first line cavities 77 is statistically distributed during manufacturing, and thus, a fraction of the processed devices may have an overlay error that is close to or equal to zero to produce the configuration illustrated in FIG. 16.

Referring to all drawings and according to various embodiments of the present disclosure, a device comprises: a first interconnect-level dielectric layer 70 embedding a first conductive interconnect structure (76, 78) that comprises a first conductive line portion 78; a first etch-stop dielectric layer 71 comprising a first etch-stop dielectric material and including a first line-shaped opening 73 therein; a first complementary dielectric fill material portion 79 filling the first line-shaped opening 73 and having a pair of bottom edges that coincide with a pair of edges of a top surface of the first conductive line portion 78; and a second interconnect-level dielectric layer 80 overlying the first etch-stop dielectric layer 71 and the first complementary dielectric fill material portion 79 and embedding a second conductive interconnect structure (86, 88) that comprises a conductive via portion 86 that vertically extends through a lower portion of the second interconnect-level dielectric layer 80 and through the first complementary dielectric fill material portion 79, and has a first bottom surface segment that contacts the first conductive line portion 78.

In one embodiment, a semiconductor device 20 is located over the substrate 8 and below the first interconnect-level dielectric layer 70.

In one embodiment, an entirely of the first conductive interconnect structure (76, 78) is located below a horizontal plane including the top surface of the first conductive line portion 78. In one embodiment, the pair of bottom edges of the first complementary dielectric fill material portion 79 laterally extends along a first horizontal direction with a uniform lateral spacing therebetween; the first conductive interconnect structure (76, 78) comprises an integrated line-and-via structure that comprises a first conductive via portion 86 that is adjoined to a bottom end of the first conductive line portion 78; and a width of a topmost portion of the first conductive via portion 86 along a second horizontal direction that is perpendicular to the first horizontal direction is the same as a width of a bottommost portion of the first conductive line portion 78 along the second horizontal direction, and is less than the uniform lateral spacing.

In one embodiment, the conductive via portion 86 of the second conductive interconnect structure (86, 88) comprises a second bottom surface segment that contacts a segment of a top surface of the first etch-stop dielectric layer 71. In one embodiment, the conductive via portion 86 of the second conductive interconnect structure (86, 88) comprises a first tapered sidewall segment that connects the first bottom surface segment and the second bottom surface segment and contacts a segment of a sidewall of the first etch-stop dielectric layer 71. In one embodiment, the first tapered sidewall segment of the conductive via portion 86 of the second conductive interconnect structure (86, 88) has a first taper angle a relative to a vertical direction; and a sidewall of the conductive via portion 86 of the second conductive interconnect structure (86, 88) in contact with the second interconnect-level dielectric layer 80 has a second taper angle b relative to the vertical direction that is different from the first taper angle a. In one embodiment, a lower portion of the conductive via portion 86 of the second conductive interconnect structure (86, 88) is in contact with a surface segment of the first complementary dielectric fill material portion 79.

In one embodiment, a top surface of the first complementary dielectric fill material portion 79 is located in a same horizontal plane as a top surface of the first etch-stop dielectric layer 71. In one embodiment, the first complementary dielectric fill material portion 79 has a different material composition than the second interconnect-level dielectric layer 80.

In one embodiment, a horizontal plane including the pair of bottom edges of the first complementary dielectric fill material portion 79 and the pair of edges of the top surface of the first conductive line portion 78 is located above a horizontal plane including an interface between a bottom surface of the first etch-stop dielectric layer 71 and a top surface of the first interconnect-level dielectric layer 70. Alternatively, a horizontal plane including the pair of bottom edges of the first complementary dielectric fill material portion 79 and the pair of edges of the top surface of the first conductive line portion 78 is located below a horizontal plane including an interface between a bottom surface of the first etch-stop dielectric layer 71 and a top surface of the first interconnect-level dielectric layer 70. Yet alternatively, the pair of bottom edges of the first complementary dielectric fill material portion 79 and the pair of edges of the top surface of the first conductive line portion 78 are located within a horizontal plane including an interface between a bottom surface of the first etch-stop dielectric layer 71 and a top surface of the first interconnect-level dielectric layer 70.

In one embodiment, an entirety of a top surface of the first complementary dielectric fill material portion 79 is located within a horizontal plane including a top surface of the first etch-stop dielectric layer 71; and a thickness of the first complementary dielectric fill material portion 79 is different from a thickness of the first etch-stop dielectric layer 71. In one embodiment, the second conductive interconnect structure (86, 88) comprises an integrated line-and-via structure that comprises a second conductive line portion that is adjoined to an upper end of the conductive via portion 86 of the second conductive interconnect structure (86, 88).

The various embodiments of the present disclosure provide a structure and processing method for reducing time-dependent dielectric breakdown (TDDB) in conductive interconnect structures. Self-aligned via structures (such as the second conductive via portions 86 described above) may be formed employing a single etch-stop dielectric layer (such as the first etch-stop dielectric layer 71 described above). The lateral spacing between each self-aligned via structure and an adjacent conductive line (such as an adjacent first conductive line portion 78) can be maintained above a predetermined minimum value that is defined by the lateral dimension between neighboring pairs of line-shaped openings (such as the first line-shaped openings 73) in the etch-stop dielectric layer. The embodiments of the present disclosure can be employed to provide a CMOS circuit requiring high device density and low leakage current, such as a sense amplifier circuit for a memory array. However, the devices of the embodiments of the present disclosure may located in any other suitable circuit.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A device, comprising:
a first interconnect-level dielectric layer embedding a first conductive interconnect structure that comprises a first conductive line portion;
a first etch-stop dielectric layer comprising a first etch-stop dielectric material and including a first line-shaped opening therein;
a first complementary dielectric fill material portion filling the first line-shaped opening and having a pair of bottom edges that coincide with a pair of edges of a top surface of the first conductive line portion; and
a second interconnect-level dielectric layer overlying the first etch-stop dielectric layer and the first complementary dielectric fill material portion and embedding a second conductive interconnect structure that comprises a conductive via portion that vertically extends through a lower portion of the second interconnect-level dielectric layer and through the first complementary dielectric fill material portion, and has a first bottom surface segment that contacts the first conductive line portion.

2. The device of claim 1, further comprising a semiconductor device located over substrate and below the first interconnect-level dielectric layer.

3. The device of claim 1, wherein an entirely of the first conductive interconnect structure is located below a first horizontal plane including the top surface of the first conductive line portion.

4. The device of claim 1, wherein:
the pair of bottom edges of the first complementary dielectric fill material portion laterally extends along a first horizontal direction with a uniform lateral spacing therebetween;
the first conductive interconnect structure comprises an integrated line-and-via structure that comprises a first conductive via portion that is adjoined to a bottom end of the first conductive line portion; and
a width of a topmost portion of the first conductive via portion along a second horizontal direction that is perpendicular to the first horizontal direction is the same as a width of a bottommost portion of the first conductive line portion along the second horizontal direction, and is less than the uniform lateral spacing.

5. The device of claim 1, wherein the conductive via portion of the second conductive interconnect structure further comprises a second bottom surface segment that contacts a segment of a top surface of the first etch-stop dielectric layer.

6. The device of claim 5, wherein the conductive via portion of the second conductive interconnect structure further comprises a first tapered sidewall segment that connects the first bottom surface segment and the second bottom surface segment and contacts a segment of a sidewall of the first etch-stop dielectric layer.

7. The device of claim 6, wherein:
the first tapered sidewall segment of the conductive via portion of the second conductive interconnect structure has a first taper angle relative to a vertical direction; and
a sidewall of the conductive via portion of the second conductive interconnect structure in contact with the second interconnect-level dielectric layer has a second taper angle relative to the vertical direction that is different from the first taper angle.

8. The device of claim 5, wherein a lower portion of the conductive via portion of the second conductive interconnect structure is in contact with a surface segment of the first complementary dielectric fill material portion.

9. The device of claim 1, wherein a top surface of the first complementary dielectric fill material portion is located in a same horizontal plane as a top surface of the first etch-stop dielectric layer.

10. The device of claim 1, wherein the first complementary dielectric fill material portion has a different material composition than the second interconnect-level dielectric layer.

11. The device of claim 1, wherein a horizontal plane including the pair of bottom edges of the first complementary dielectric fill material portion and the pair of edges of the top surface of the first conductive line portion is located above a horizontal plane including an interface between a bottom surface of the first etch-stop dielectric layer and a top surface of the first interconnect-level dielectric layer.

12. The device of claim 1, wherein a horizontal plane including the pair of bottom edges of the first complementary dielectric fill material portion and the pair of edges of the top surface of the first conductive line portion is located below a horizontal plane including an interface between a bottom surface of the first etch-stop dielectric layer and a top surface of the first interconnect-level dielectric layer.

13. The device of claim 1, wherein the pair of bottom edges of the first complementary dielectric fill material portion and the pair of edges of the top surface of the first conductive line portion are located within a horizontal plane including an interface between a bottom surface of the first etch-stop dielectric layer and a top surface of the first interconnect-level dielectric layer.

14. The device of claim 1, wherein:
an entirety of a top surface of the first complementary dielectric fill material portion is located within a horizontal plane including a top surface of the first etch-stop dielectric layer; and
a thickness of the first complementary dielectric fill material portion is different from a thickness of the first etch-stop dielectric layer.

15. The device of claim 1, wherein the second conductive interconnect structure comprises an integrated line-and-via structure that further comprises a second conductive line portion that is adjoined to an upper end of the conductive via portion of the second conductive interconnect structure.

16. A method of forming a device, comprising:
forming a first interconnect-level dielectric layer;
forming a first etch-stop dielectric layer comprising a first etch-stop dielectric material and including a first line-shaped opening therein over the first interconnect-level dielectric layer;
forming a first line cavity in an upper portion of the first interconnect-level dielectric layer by transferring a pattern of the first line-shaped opening into an upper portion of the first interconnect-level dielectric layer;
forming a first conductive interconnect structure that comprises a first conductive line portion in the first interconnect-level dielectric layer, wherein the first conductive line portion is formed within a volume of the first line cavity and has a top surface located below a horizontal plane including a top surface of the first etch-stop dielectric layer;
forming a first complementary dielectric fill material portion over the first conductive interconnect structure within the first line-shaped opening, wherein a top surface of the first complementary dielectric fill material portion is formed within the horizontal plane including a top surface of the first etch-stop dielectric layer;
forming a second interconnect-level dielectric layer over the first etch-stop dielectric layer and the first complementary dielectric fill material portion; and
forming a second conductive interconnect structure in the second interconnect-level dielectric layer, wherein the second conductive interconnect structure comprises a conductive via portion that vertically extends through a lower portion of the second interconnect-level dielectric layer and through the first complementary dielectric fill material portion, and has a first bottom surface segment that contacts the first conductive line portion.

17. The method of claim 16, wherein the first conductive interconnect structure is formed by:
depositing at least one electrically conductive material within a void that comprises volumes of the first line-shaped opening and the first line cavity and over the first etch-stop dielectric layer;
performing a chemical mechanical polishing process that removes portions of the at least one electrically conductive material from above the horizontal plane including the top surface of the first etch-stop dielectric layer; and
vertically recessing the at least one electrically conductive material after the chemical mechanical polishing process, wherein a remaining portion of the at least one electrically conductive material comprise the first conductive interconnect structure.

18. The method of claim 16, wherein the first complementary dielectric fill material portion is formed by:
depositing a dielectric fill material over the top surface of the first conductive interconnect structure and over the first etch-stop dielectric layer; and
performing a chemical mechanical polishing process that removes portions of the dielectric fill material from above the horizontal plane including the top surface of the first etch-stop dielectric layer, wherein a remaining portion of the dielectric fill material comprises the first complementary dielectric fill material portion.

19. The method of claim 16, further comprising:
forming a semiconductor device over a substrate, wherein the semiconductor device is located below the first interconnect-level dielectric layer;
forming a second etch-stop dielectric layer comprising a second etch-stop dielectric material and including an opening therein over the second interconnect-level dielectric layer;
forming a via cavity through the second interconnect-level dielectric layer within an area that is located entirely within an area of the opening in the second etch-stop dielectric layer by performing an anisotropic etch process that etches dielectric materials of the second interconnect-level dielectric layer and the first complementary dielectric fill material portion selective to materials of the first etch-stop dielectric layer and the first conductive interconnect structure;
depositing at least one electrically conductive material within the via cavity and over the second etch-stop dielectric layer; and
removing portions of the at least one electrically conductive material above a horizontal plane that is located below a horizontal plane including a top surface of the second etch-stop dielectric layer, wherein a remaining portion of the at least one electrically conductive material comprise the second conductive interconnect structure.

20. The method of claim 16, further comprising:
forming a photoresist layer comprising a discrete opening over the first etch-stop dielectric layer after formation of the first line cavity;
performing an anisotropic etch process that etches portions of the first interconnect-level dielectric layer located within an area in which the discrete opening overlaps with the first line cavity in a plan view from underneath the first line cavity, whereby a first via cavity that is adjoined to the first line cavity is formed;
depositing at least one electrically conductive material within a combination of the first via cavity, the first line cavity, and the first line-shaped opening; and
removing the at least one electrically conductive material from above an additional horizontal plane that underlies the horizontal plane including the top surface of the first etch-stop dielectric layer, wherein a remaining portion of the at least one electrically conductive material comprises the first conductive interconnect structure.
